(19) United States
(12) Patent Application Publication
(10) Pub. No.: US 2001/0017109 A1
(43) Pub. Date: Aug. 30, 2001

(54) ENHANCED PLASMA MODE AND SYSTEM FOR PLASMA IMMERSION ION IMPLANTATION

(76) Inventors: WEI LIU, SAN JOSE, CA (US); MICHAEL A. BRYAN, LOS GATOS, CA (US); IAN S. ROTH, PALO ALTO, CA (US); CHUNG CHAN, NEWTON, MA (US)

Correspondence Address: TOWNSEND AND TOWNSEND AND CREW LLP, TWO EMBARCADERO CENTER, 8TH FLOOR, SAN FRANCISCO, CA, 941113834

(21) Appl. No.: 09/451,204

(22) Filed: Nov. 29, 1999

Related U.S. Application Data
(60) Provisional application No. 60/110,526, filed on Dec. 1, 1998.

(51) Int. Cl. C23C 16/507

(52) U.S. Cl. 118/723 I; 156/345

(57) ABSTRACT

A novel plasma treatment system (200). The plasma treatment system has a chamber (14), where a vacuum is maintained. The system also has a susceptor disposed within an interior region in the chamber. The susceptor (i.e., electrostatic chuck) is adapted to secure a work piece thereon. The system has an rf source (40) disposed overlying the susceptor. The rf source provides an inductive discharge to form a plasma from a gas within the chamber. Magnetic sources (207), (209) are selectively applied to the plasma discharge. In a specific embodiment, a first magnetic source (207) is disposed surrounding the susceptor in the chamber. The first magnetic source provides focused magnetic field lines toward the susceptor. A second magnetic source (209) is disposed surrounding the susceptor, where the second magnetic source provides focussed magnetic field lines toward the susceptor. The combination of the rf source and the magnetic sources form a plasma discharge that is shaped as a “cusp” which focuses the plasma discharge.

### CROSS-REFERENCE TO RELATED PATENT APPLICATIONS

The following five commonly-owned co-pending applications, including this one, are being filed concurrently and the other four are hereby incorporated by reference in their entirety for all purposes:

1. U.S. patent application Ser. No. ______, Wei Liu, et al., entitled, “Enhanced Plasma Mode and System For Plasma Immersion Ion Implantation,” (Attorney Docket Number 18419-0071000);

2. U.S. patent application Ser. No. ______, Wei Liu, et al., entitled, “Enhanced Plasma Mode and Method For Plasma Immersion Ion Implantation,” (Attorney Docket Number 18419-072000);

3. U.S. patent application Ser. No., ______, Wei Liu, et al., entitled, “Enhanced Plasma Mode and Computer System For Layer Transfer Processes,” (Attorney Docket Number 18419-073000);

4. U.S. Provisional Patent Application Ser. No., ______, Wei Liu, et al., entitled, “Enhanced Plasma Mode, Method, and System For Domed Chamber Designs,” (Attorney Docket Number SGC-101/TTC18419-074000); and

### BACKGROUND OF THE INVENTION

The present invention relates to the manufacture of objects. More particularly, the present invention provides a technique for providing a combination of a plasma discharge and an applied magnetic field for creating a high-density plasma source. The present invention can be applied to implanting particles for the manufacture of integrated circuits, for example. But it will be recognized that the invention has a wider range of applicability; it can also be applied to implanting particles for other substrates such as multi-layered integrated circuit devices, three-dimensional packaging of integrated semiconductor devices, photonic devices, piezoelectronic devices, microelectromechanical systems (“MEMS”), sensors, actuators, solar cells, flat panel displays (e.g., LCD, AMLCD), doping semiconductor devices, biological and biomedical devices, and the like.

Integrated circuits are fabricated on chips of semiconductor material. These integrated circuits often contain thousands, or even millions, of transistors and other devices. In particular, it is desirable to put as many transistors as possible within a given area of semiconductor because more transistors typically provide greater functionality, and a smaller chip means more chips per wafer and lower costs. Some integrated circuits are fabricated on a slice or wafer, of single-crystal (monocrystalline) silicon, commonly termed a “bulk” silicon wafer. Devices on such “bulk” silicon wafer typically are made by processing techniques such as ion implantation or the like to introduce impurities or ions into the substrate. These impurities or ions are introduced into the substrate to selectively change the electrical characteristics of the substrate, and therefore devices being formed on the substrate. Ion implantation provides accurate placement of impurities or ions into the substrate. Ion implantation, however, is expensive and generally cannot be used effectively for introducing impurities into a larger substrate such as glass or a semiconductor substrate, which is used for the manufacture of flat panel displays or the like.

Accordingly, plasma treatment of large area substrates such as glass or semiconductor substrates has been proposed or used in the fabrication of flat panel displays or 300 millimeter silicon wafers. Plasma treatment is commonly called plasma immersion ion implantation (“PIII”) or plasma source ion implantation (“PSI”). Plasma treatment generally uses a chamber, which has an inductively coupled plasma source, for generating and maintaining a plasma therein. A large voltage differential between the plasma and the substrate to be implanted accelerates impurities or ions from the plasma into the surface or depth of the substrate. A variety of limitations exist with the convention plasma processing techniques.

A major limitation with conventional plasma processing techniques is the maintenance of the uniformity of the plasma density and chemistry over such a large area is often difficult. As merely an example, inductively or transformer coupled plasma sources (“ICP” and “TCP,” respectively) are affected both by difficulties of maintaining plasma uniformity using inductive coil antenna designs. Additionally, these sources are often costly and generally difficult to maintain, in part, because such sources typically require large and thick quartz windows for coupling the antenna radiation into the processing chamber. The thick quartz windows often cause an increase in radio frequency (“rf”) power (or reduction in efficiency) due to heat dissipation within the window.

Other techniques such as Electron Cyclotron Resonance (“ECR”) and Helicon type sources are limited by the difficulty in scaling the resonant magnetic field to large areas when a single antenna or wave guide is used. Furthermore, most ECR sources utilize microwave power. Microwave power is often more expensive and difficult to tune electrically. Hot cathode plasma sources have been used or proposed. The hot cathode plasma sources often produce contamination of the plasma environment due to the evaporation of cathode material. Alternatively, cold cathode sources have also be used or proposed. These cold cathode sources often produce contamination due to exposure of the cold cathode to the plasma generated.

A pioneering technique has been developed to improve or, perhaps, even replace these conventional sources for implantation of impurities. This technique has been developed by Dr. Chung Chan of Waban Technology in Massachusetts, now Silicon Genesis Corporation, and has been described in U.S. Pat. No. 5,653,811 (“Chan”), which is hereby incorporated by reference herein for all purposes. Chan generally describes techniques for treating a substrate with a plasma with an improved plasma processing system. The improved plasma processing system, includes, among other elements, at least two rf sources, which are operative to generate a plasma in a vacuum chamber. By way of the multiple sources, the improved plasma system provides a more uniform plasma distribution during implantation, for example. It is still desirable, however, to provide even a more uniform plasma for the manufacture of substrates.

From the above, it is seen that an improved technique for introducing impurities into a substrate is highly desired.

### SUMMARY OF THE INVENTION

According to the present invention, a technique including a method and system for providing a high-density plasma source is provided. In an exemplary embodiment, the present invention provides an apparatus that uses a combination of a high frequency source and a magnetic source to form a high-density plasma. The high-density plasma source can provide a plasma that is substantially a single isotope of hydrogen, for example.

In a specific embodiment, the present invention provides a novel plasma treatment system. The plasma treatment system has a chamber, where a vacuum is maintained. The system also has a susceptor disposed within an interior region in the chamber. The susceptor (i.e., electrostatic chuck) is adapted to secure a work piece thereon. The system has an rf source disposed overlying the susceptor. The rf source provides an inductive discharge to form a plasma from a gas (e.g., hydrogen, oxygen, argon, boron, and silane) within the chamber. Magnetic sources are selectively applied to the plasma discharge. In a specific embodiment, a first magnetic source is disposed surrounding the susceptor in the chamber. The first magnetic source provides focused magnetic field lines toward the rf source. A second magnetic source is disposed surrounding the susceptor, where the second magnetic source provides focussed magnetic field lines toward the susceptor. The magnetic sources form a plasma discharge that is shaped in a “cusp” which focuses the plasma discharge. The cusp keeps the plasma away from walls of the chamber, which prevents recombination of plasma species. Accordingly, the present system provides a high-density discharge that is substantially a single species such as H₁⁺ and other species.

In an alternative embodiment, the present invention provides a novel plasma treatment system. The plasma treatment system has a chamber, where a vacuum is maintained. The system also has a susceptor disposed within an interior region in the chamber. The susceptor (i.e., electrostatic chuck) is adapted to secure a work piece thereon. The system has an rf source disposed overlying the susceptor. The rf source provides an inductive discharge to form a plasma from a gas within the chamber. The gas can be a single species such as hydrogen gas, oxygen gas, and others, or mixtures thereof, as well as others. A magnetic source is disposed surrounding the susceptor. The magnetic source provides focused magnetic field lines toward the susceptor. In a specific embodiment, the magnetic source forms a “cusp” near the susceptor. The combination of rf source and magnetic sources are selectively adjusted in a manner to provide a substantially pure plasma of a single ionic species, e.g., H₁⁺. The substantially pure ionic species provides a source of substantially uniform implantation.

Numerous benefits are achieved by way of the present invention. In one aspect, the present invention provides a high-density plasma source that is rich with hydrogen bearing particles in the H₁⁺ state. This high-density source is an active, which allows the hydrogen bearing particles to be implanted in a uniform manner through a surface of a substrate such as a silicon wafer. In another aspect, the present invention achieves a high-density plasma source in a simple and elegant source design, which uses a lower amount of rf power than conventional multi-coil sources. The present invention also provides a method for igniting the plasma source in a “proton” state, which is highly efficient. Depending upon the embodiment, one or more of these benefits is present. These and other advantages or benefits are described throughout the present specification and are described in more detail in conjunction with the text below and attached Figs.

### BRIEF DESCRIPTION OF THE DRAWINGS

FIG. 1 is a simplified cross-sectional schematic diagram of a conventional plasma treatment system;

FIG. 1A is a simplified schematic diagram of a conventional plasma treatment system;

FIG. 1B depicts a simplified top-view diagram of substrate in a conventional plasma treatment system;

FIG. 2 is a simplified diagram of a plasma treatment system for implanting particles according to an embodiment of the present invention;

FIG. 3 depicts a simplified plan view of configuration of plasma sources according to an alternative embodiment of the present invention;

FIGS. 4-4A depict alternate arrangements of Faraday cups used to measure the uniformity of the field and the plasma dose in one embodiment of the present invention;

FIG. 5 depicts an rf source according to another embodiment of the present invention;

FIG. 6 depicts a plasma treatment system having multiple rf sources of the type shown in FIG. 5;

FIG. 7 depicts an embodiment of the system of the invention using two plasma sources;

FIG. 8 illustrates a relative measurement of the hydrogen bearing particles in a plasma treatment system according to the present invention;

FIG. 9 is a simplified profile of an implant experiment according and embodiment of the present invention; and

FIGS. 10 and 11 depict ion mass spectrometer data at the center of a plasma for different applied powers in a system of the present invention.

### DESCRIPTION OF THE SPECIFIC EMBODIMENTS

According to the present invention, a technique including a method and system for providing a high-density plasma source is provided. In an exemplary embodiment, the present invention provides an apparatus that uses a combination of a high frequency source and a magnetic source to form a high-density plasma. The high-density plasma can provide a plasma that is substantially a single isotope of hydrogen, for example.

### 1. Conventional Plasma Processing System

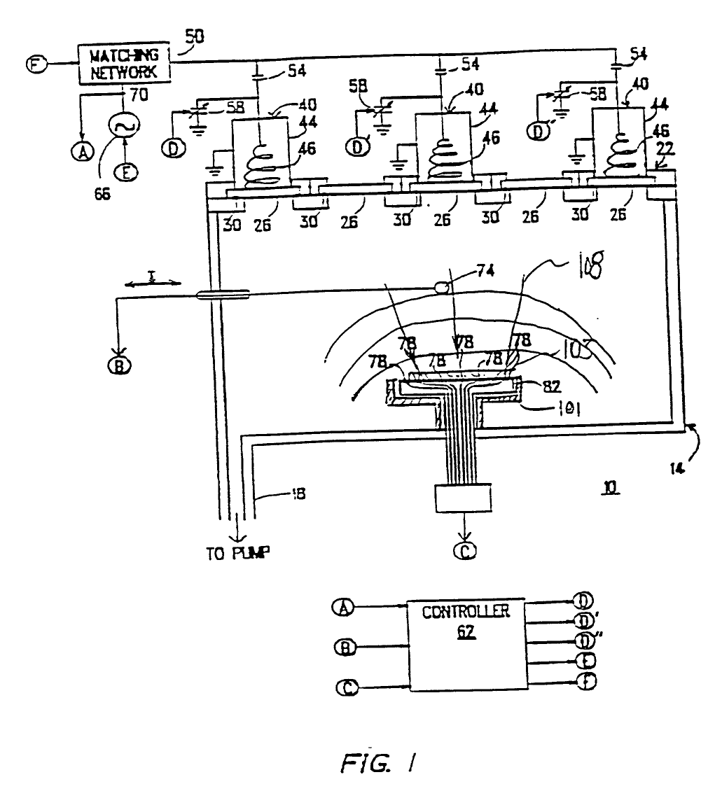

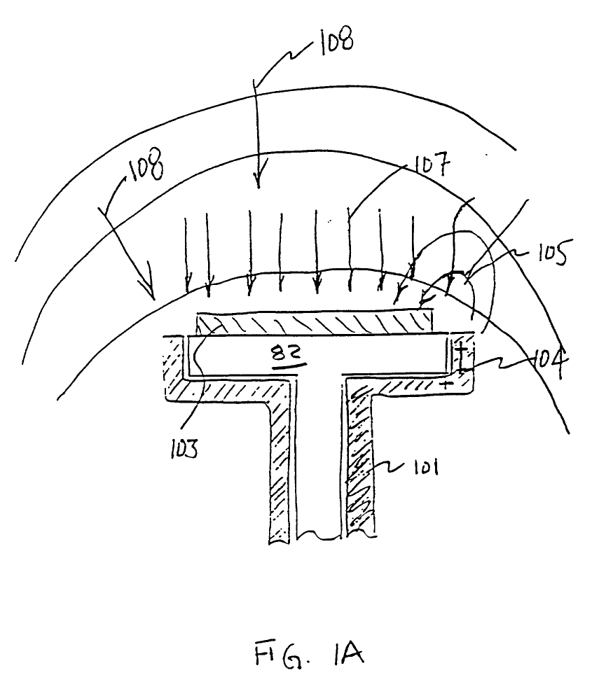

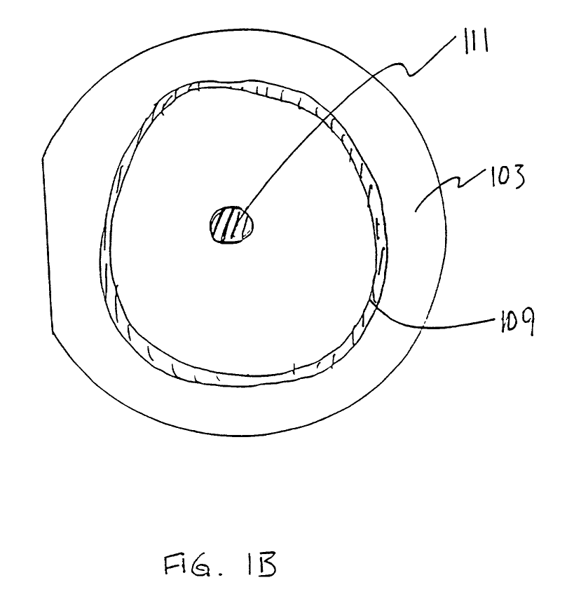

In brief overview and referring to FIG. 1, conventional plasma processing system 10 includes a vacuum chamber 14 having a vacuum port 18 connected to a vacuum pump (not shown). The system 10 includes a series of dielectric windows 26 vacuum sealed by O-rings 30 and attached by removable clamps 34 to the upper surface 22 of the vacuum chamber 14. Removably attached to some of these dielectric windows 26 are rf plasma sources 40, in a system having a helical or pancake antennae 46 located within an outer shield/ground 44. Cooling of each antenna is accomplished by passing a cooling fluid through the antenna. Cooling is typically required only at higher power. The windows 26 without attached rf plasma sources 40 are usable as viewing ports into the chamber 14. The removability of each plasma source 40 permits the associated dielectric window 26 to be cleaned or the plasma source 40 replaced without the vacuum within the system 10 being removed. Although glass windows are used, other dielectric material such as quartz or polyethylene may be used for the window material.

Each antenna 46 is connected to an rf generator 66 through a matching network 50, through a coupling capacitor 54. Each antenna 46 also includes a tuning capacitor 58 connected in parallel with its respective antenna 46. Each of the tuning capacitors 58 is controlled by a signal D, D′, D″ from a controller 62. By individually adjusting the tuning capacitors 85, the output power from each rf antenna 46 can be adjusted to maintain the uniformity of the plasma generated. Other tuning means such as zero reflective power tuning may also be used to adjust the power to the antennae. The rf generator 66 is controlled by a signal E from the controller 62. The controller 62 controls the power to the antennae 46 by a signal F to the matching network 50.

The controller 62 adjusts the tuning capacitors 58 and the rf generator 66 in response to signals A, B, and C. Here, signal A is from a sensor 70 monitoring the power delivered to the antennae 46. Signal B is from a fast scanning Langmuir probe 74 directly measuring the plasma density. Signal C is from a plurality of Faraday cups 78 attached to a substrate wafer holder 82. The Langmuir probe 74 is scanned by moving the probe (double arrow I) into and out of the plasma. With these sensors, the settings for the rf generator 66 and the tuning capacitors 58 may be determined by the controller prior to the actual use of the system 10 to plasma treat a substrate. Once the settings are determined, the probes are removed and the wafer to be treated is introduced. The probes are left in place during processing to permit real time control of the system. Care must be taken to not contaminate the plasma with particles evaporating from the probe and to not shadow the substrate being processed.

This conventional system has numerous limitations. For example, the conventional system 10 includes wafer holder 82 that is surrounded by a quartz liner 101. The quartz liner is intended to reduce unintentional contaminants sputtered from the sample stage to impinge or come in contact with the substrate 103, which should be kept substantially free from contaminates. Additionally, the quartz liner is intended to reduce current load on the high voltage modulator and power supply. The quartz liner, however, often attracts impurities or ions 104 that attach themselves to the quartz liner by way of charging, as shown by FIG. 1A. By way of this attachment, the quartz liner becomes charged, which changes the path of ions 105 from a normal trajectory 107. The change in path can cause non-uniformities during a plasma immersion implantation process. FIG. 1B shows a simplified top-view diagram of substrate 103 that has high concentration regions 111 and 109, which indicate non-uniformity. In some conventional systems, the liner can also be made of a material such as aluminum. Aluminum is problematic in conventional processing since aluminum particles can sputter off of the liner and attach themselves to the substrate. Aluminum particles on the substrate can cause a variety of functional and reliability problems in devices that are manufactured on the substrate. A wafer stage made of stainless steel can introduce particulate contamination such as iron, chromium, nickel, and others to the substrate. A paper authored by Zhineng Fan, Paul K. Chu, Chung Chan, and Nathan W. Cheung, entitled “Dose and Energy Non-Uniformity Caused By Focusing Effects During Plasma Immersion Ion Implantation,” published in “Applied Physics Letters” describes some of the limitations mentioned herein.

Additionally, the conventional system introduces ions 108 toward the substrate surface in a non-uniform manner. As shown, ions accelerate toward the substrate surface at varying angles and fluxes. These varying angles and fluxes tend to create a non-uniform ion distribution in the substrate material. The non-uniform distribution of ions in the substrate can create numerous problems. For example, a non-uniform distribution of ions in a substrate used for a film transfer process or a controlled cleaving process can ultimately create a non-uniform detached film, which is highly undesirable in the manufacture of integrated circuits. Accordingly, it is generally desirable to form a uniform distribution of ions at a selected depth in the substrate material for film transfer processes.

### 2. Present Plasma Immersion Systems

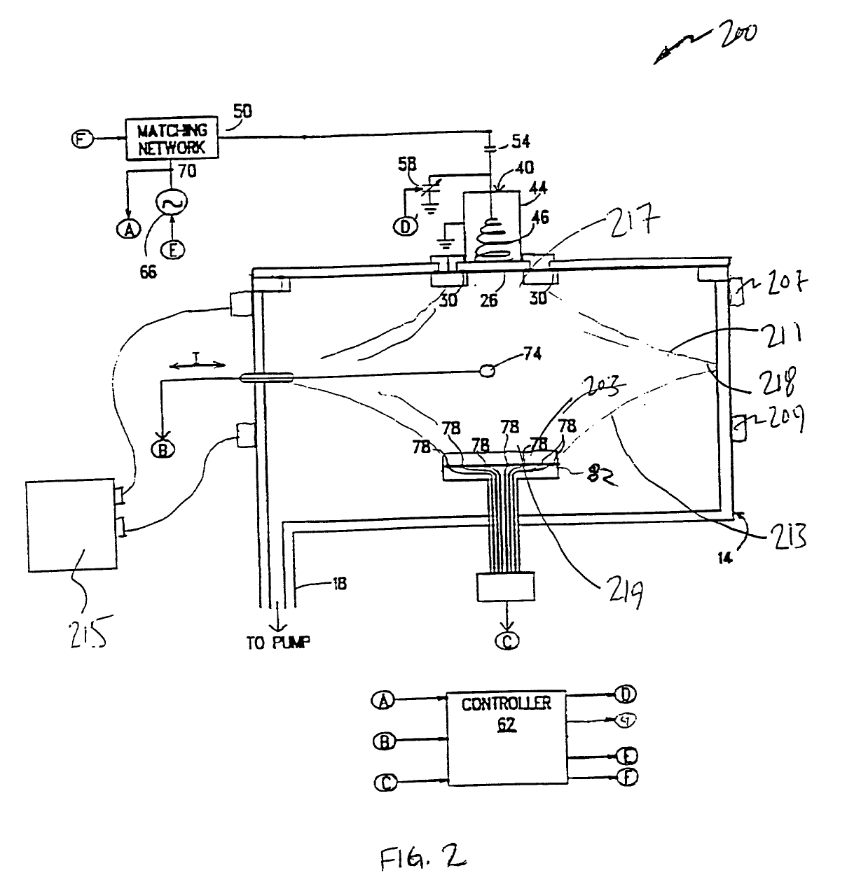

FIG. 2 is a simplified overview of a plasma treatment system 200 for implanting particles according to an embodiment of the present invention. This diagram is merely an illustration and should not limit the scope of the claims herein. One of ordinary skill in the art would recognize other variations, modifications, and alternatives. For easy reading, some of the reference numerals used in FIG. 1 are used in FIG. 2 and others. In a specific embodiment, system 200 includes a vacuum chamber 14 having a vacuum port 18 connected to a vacuum pump (not shown). The system 200 includes a dielectric window 26 vacuum-sealed by O-rings 30 and attached by removable clamps 34 to the upper surface 22 of the vacuum chamber 14. Removably attached to the dielectric window 26 is an rf plasma source 40, in one embodiment having a helical or pancake antennae 46 located within an outer shield/ground 44. Other embodiments of the antennae using capacitive or inductive coupling may be used. The rf plasma source can be operated at 13.56 MHz, and other frequencies. The rf plasma source typically provides between about 0 kW and about 10 kW of rf power. Cooling of each antenna is accomplished by passing a cooling fluid through the antenna. Cooling is typically required only at higher power. The window 26 without attached rf plasma sources 40 is usable as a viewing port into the chamber 14. The removability of each plasma source 40 permits the associated dielectric window 26 to be cleaned or the plasma source 40 replaced without the vacuum within the system 10 being removed. Although a glass window is used in this embodiment, other dielectric materials such as quartz or polyethylene may be used for the window material.

Antenna 46 is connected to an rf generator 66 through a matching network 50, through a coupling capacitor 54. Antenna 46 also includes a tuning capacitor 58 connected in parallel with its respective antenna 46. The tuning capacitor 58 is controlled by a signal D from a controller 62. By adjusting the tuning capacitor 85, the output power from the rf antenna 46 can be adjusted to maintain the uniformity of the plasma generated. Other tuning means such as zero reflective power tuning may also be used to adjust the power to the antennae. In one embodiment, the rf generator 66 is controlled by a signal E from the controller 62. In one embodiment, the controller 62 controls the power to the antennae 46 by a signal F to the matching network 50.

The controller 62 adjusts the tuning capacitor 58 and the rf generator 66 in response to signals A, B, and C. Signal A is from a sensor 70 (such as a Real Power Monitor by Comdel, Inc., Beverly, Mass.) monitoring the power delivered to the antennae 46. Signal B is from a fast scanning Langmuir probe 74 directly measuring the plasma density. Signal C is from a plurality of Faraday cups 78 attached to a substrate wafer holder 82. The Langmuir probe 74 is scanned by moving the probe (double arrow I) into and out of the plasma. With these sensors, the settings for the rf generator 66 and the tuning capacitors 58 may be determined by the controller prior to the actual use of the system 200 to plasma treat a substrate. Once the settings are determined, the probes are removed and the wafer to be treated is introduced. In another embodiment of the system, the probes are left in place during processing to permit real time control of the system. In such an embodiment using a Langmuir probe, care must be taken to not contaminate the plasma with particles evaporating from the probe and to not shadow the substrate being processed. In yet another embodiment of the system, the characteristics of the system are determined at manufacture and the system does not include a plasma probe.

In a preferred embodiment, a magnetic field is applied to the plasma in the vacuum chamber 14. In a specific embodiment, an electro-magnetic source 207 is applied to an upper vessel portion and an electro-magnetic source 209 is applied to a lower vessel portion. These sources and others shape the plasma to form magnetic field lines 211 and 213, which push or shape the plasma away from walls of the vessel. In a specific embodiment, the electro-magnetic source can be a conductor such as a plurality of wires or cables, which conduct current. Alternatively, the magnetic source can be a single conductive member that carries electric current, which forms a magnetic field. In a specific embodiment, the conductor is a plurality of wires, which are wrapped around the periphery of the vessel. The wires are suitably constructed such that they carry enough electric current to influence the plasma in the vessel. In one embodiment, the wires are a plurality of insulated wires that are wrapped around a periphery of the vessel. The insulated wires each include a conductive core.

A power source(s) supplies direct current to the magnetic sources. Magnetic source 207 couples to a power source 215, which supplies direct current in one direction to the wires. Magnetic source 209 couples to power source 215, which supplies direct current in another direction (which is opposite of magnetic source 207). The power source can be any suitable power source such as a DC power supply. The power source is capable of supplying direct current to about 50 amps at up to about 50 volts. A power rating of about 2,500 watts or greater is also desirable, but is not limiting.

In a specific embodiment, a combination of the rf plasma source 40 and electro-magnetic sources 207, 209 create “cusp” regions 217, 218, and 219. Here, the combined sources 207, 209 are operated in a manner that maintains a substantial portion of the plasma to be confined within a spatial area away from the walls. By way of this confinement, recombination of the plasma species near the walls is reduced. Combination of the sources also provides for a higher plasma density. The high-density plasma uses inductive coupling from the rf plasma source and uses the magnetic sources 207 and 209 to shape the plasma. The shaped plasma also has a much higher energy and density than the plasma created by only the rf plasma source. The high-density plasma can be used for a number of applications including, plasma immersion ion implantation and others. In some embodiments, a cooling source (not shown) can be applied near an outer wall of the chamber near cusp region 218, which is often concentrated with electrons. The electrons create additional heat near the chamber wall that should be removed by way of the cooling source.

Controller 62 is used to control power to the magnetic sources 207 and 209. Controller 62 includes output G, which selectively adjusts the amount of direct current provided to magnetic source 207. Output G can also selectively adjusts the amount of direct current provided to magnetic source 209. The output can be determined by way of signal B from a fast scanning Langmuir probe 74 directly measuring the plasma density. Alternatively, the output can be determined by signal C, which is from a plurality of Faraday cups 78 attached to a substrate wafer holder 82. The Langmuir probe 74 is scanned by moving the probe (double arrow I) into and out of the plasma. With these sensors, the settings for power supply 215 and for the rf generator 66 and the tuning capacitors 58 may be determined by the controller prior to the actual use of the system 200 to plasma treat a substrate. Once the settings are determined, the probes are removed and the wafer to be treated is introduced. In another embodiment of the system, the probes are left in place during processing to permit real time control of the system. In such an embodiment using a Langmuir probe, care must be taken to not contaminate the plasma with particles evaporating from the probe and to not shadow the substrate being processed. In yet another embodiment of the system, the characteristics of the system are determined at manufacture and the system does not include a plasma probe.

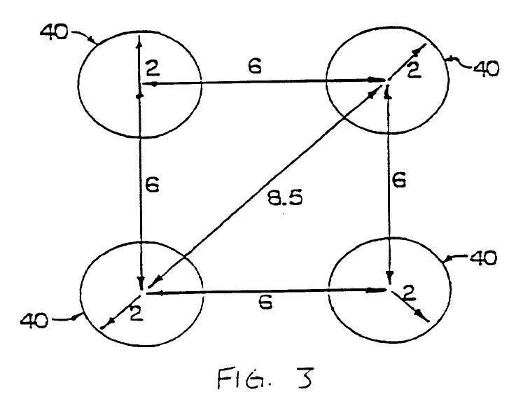

Referring to FIG. 3, the configuration of plasma sources 40 may be such that a plurality of physically smaller plasma sources 40 produce a uniform plasma over an area greater than that of sum of the areas of the individual sources. In the embodiment of the configuration shown, four-inch diameter plasma sources 40 spaced at the corners of a square at six-inch centers produce a plasma substantially equivalent to that generated by a single twelve-inch diameter source. Therefore, by providing a vacuum chamber 14 with a plurality of windows 26, the various configurations of plasma sources 40 may be formed to produce a uniform plasma of the shape and uniformity desired. Antennae such as those depicted do not result in rf interference between sources when properly shielded as shown.

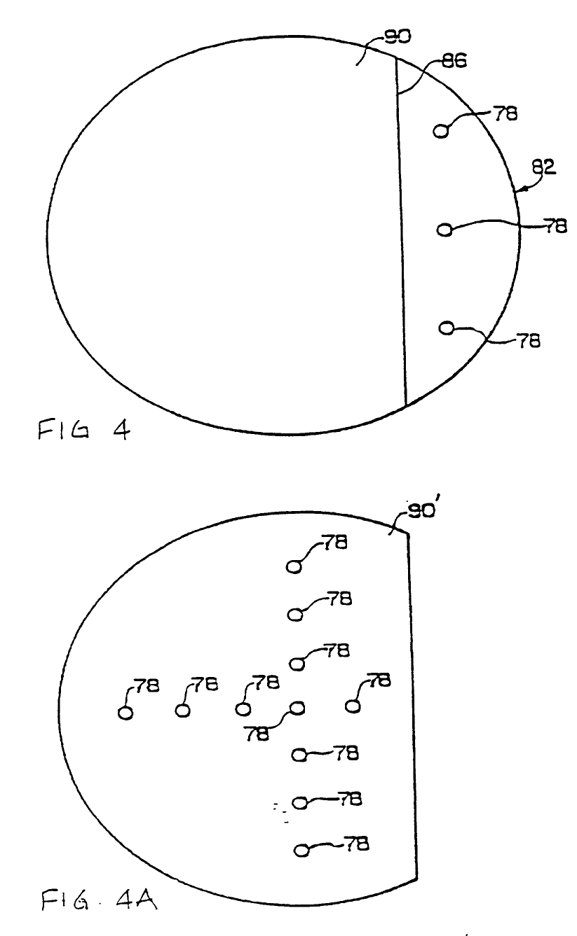

The Faraday cups 78 used to measure the uniformity of the field and the plasma dose, in one embodiment, are positioned near one edge in the surface of the wafer holder 82, which is shown in FIG. 4. The flat edge 86 of wafer 90 is positioned on the wafer holder 82 such that Faraday cups 78 of the wafer holder 82 are exposed to the plasma. In this way the plasma dose experienced by the wafer 90 can be directly measured. Alternatively, a special wafer 90′, as shown in FIG. 4A, is fabricated with a plurality of Faraday cups 78 embedded in the wafer 90′. This special wafer 90′ is used to set the rf generator 66 and the tuning capacitors 58 to achieve the desired plasma density and uniformity. Once the operating parameters have been determined, the special wafer 90′ is removed and the wafers 90 to be processed are placed on the wafer holder 82.

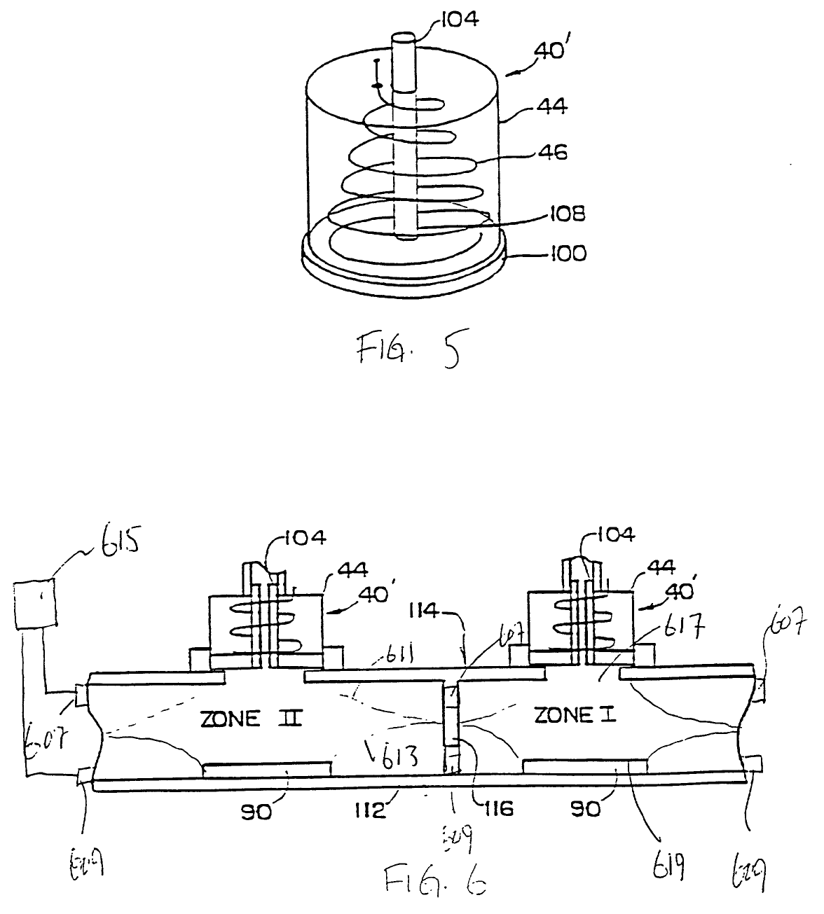

Referring to FIG. 5, in another embodiment, a quartz window 100 is not directly attached to the vacuum chamber 14, but instead encloses one end of the shield 44 of the plasma source 40′. In this embodiment, a tube 104 attached to an opening 108 in the quartz window 100 provides a gas feed to form a plasma of a specific gas. In this case, the plasma source 40′ is not attached to a window 26 in the wall of the vacuum chamber 14, but is instead attached to the vacuum chamber 14 itself. Such plasma sources 40′ can produce plasmas from specific gases as are generally required by many processes.

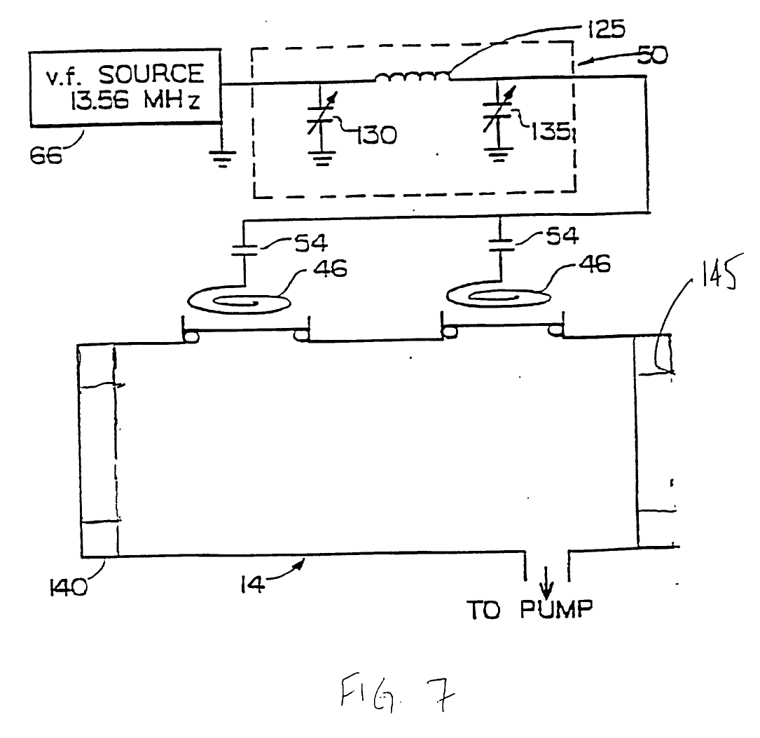

Several such plasma sources 40′ can be aligned to sequentially treat a wafer 90 with different plasmas as in the embodiment of the in line system shown in FIG. 6. In this embodiment, wafers 90 are moved by a conveyor 112 through sequential zones, in this embodiment zones I and II, of a continuous processing line 114. Each zone is separated from the adjacent zones by a baffle 116. In one embodiment, the gas in zone I is for a cleaning processing, while the gas in zone II is hydrogen used in implanting. In another embodiment, a cluster tool having load-locks to isolate each processing chamber from the other chambers, and equipped with a robot includes the rf plasma sources 40 of the invention for plasma CVD, plasma etching, plasma immersion ion implantation, ion shower, or any non-mass separated ion implantation technique.

A magnetic field is applied to plasma in the vacuum chamber 114. In a specific embodiment, an electro-magnetic source 607 is applied to an upper vessel portion and an electro-magnetic source 609 is applied to a lower vessel portion. These sources shape the plasma to form magnetic field lines 611 and 613, which push and shape the plasma away from walls of the vessel. In a specific embodiment, the electro-magnetic source can be a single or multiple conductors such as a plurality of wires or cables, which conduct current. In a specific embodiment, the conductor is a plurality of wires, which are wrapped around the periphery of the vessel. The wires are suitably constructed such that they carry enough electric current to influence the plasma in the vessel. In one embodiment, the wires are a plurality of insulated wires that are wrapped around a periphery of the vessel. The insulated wires each include a conductive core. Magnetic source 607 couples to a power source 615, which supplies direct current in one direction to the wires. Magnetic source 609 couples to power source 615, which supplies direct current in another direction (which is opposite of magnetic source 607). The power source can be any suitable power source such as a DC power supply product made by a company called Hewlett Packard, but is not limited.

In a specific embodiment, a combination of rf plasma sources 40′ and electro-magnetic sources 607, 609 create “cusp” regions 617 and 619. Here, the combination of the sources are operated in a manner which maintains a substantial portion of the plasma confined to a spatial area away from the walls, which prevents recombination of plasma species near the walls. Combination of the sources also provides for a higher plasma density. The high-density plasma uses inductive coupling from the rf plasma source and uses the magnetic sources 607 and 609 to shape the plasma. The shaped plasma also has a much higher energy and density than the plasma created by only the rf plasma source. The high-density plasma can be used for a number of applications including, plasma immersion ion implantation and others.

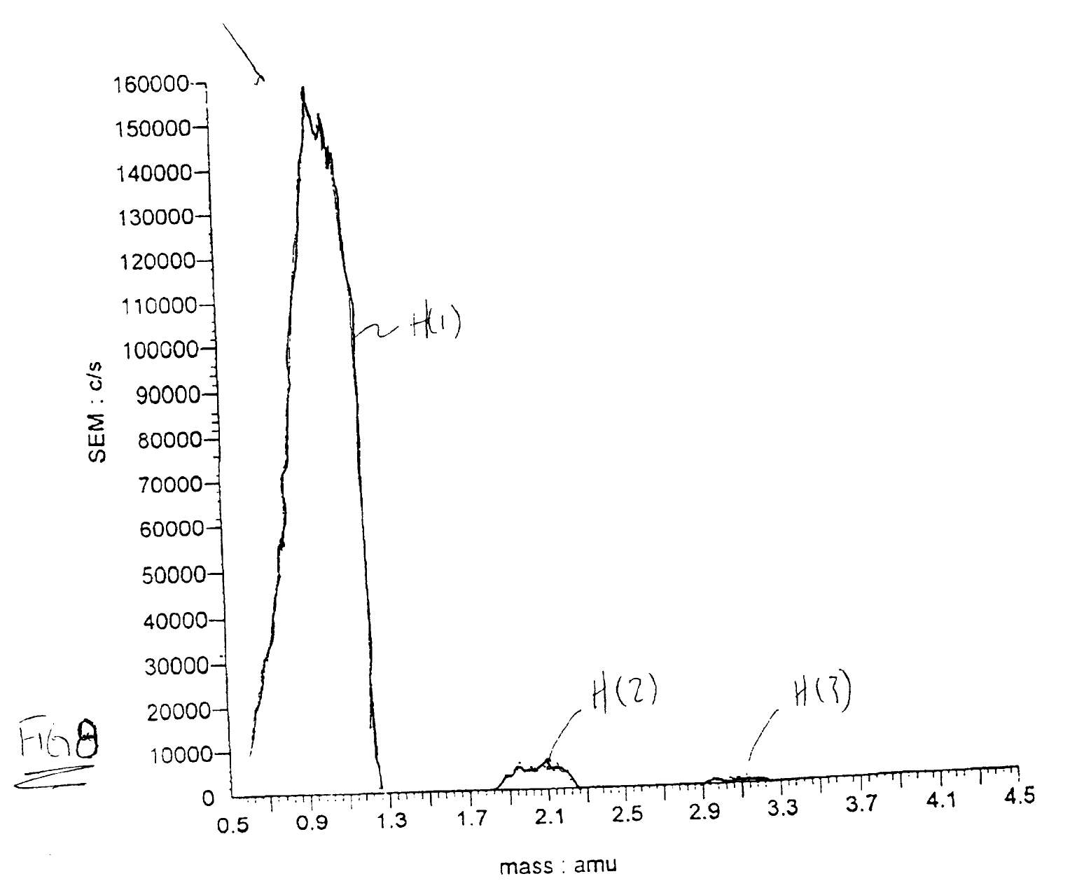

FIG. 7 depicts an embodiment of the system of the invention using two plasma sources. In this embodiment each source is an inductive pancake antenna 3-4 inches in diameter. Each antenna 46 is constructed of a ¼ inch copper tube and contains 5-6 turns. Each antenna 46 is connected to a matching network 50 through a respective 160 pf capacitor. The matching network 50 includes a 0.03 μH inductor 125 and two variable capacitors 130, 135. One variable capacitor 130 is adjustable over the range of 10-250 pf and the second capacitor 135 is adjustable over the range of 5-120 pf. The matching network 50 is tuned by adjusting the variable capacitor 130, 135. The matching network 50 is in turn connected to an rf source 66 operating at 13.56 MHz or other suitable frequencies. Electro magnetic sources 140, 145 are positioned around the circumference of the chamber. These sources include a conductive wire(s) 140, which is wrapped around a lower portion of the chamber. The wires 140 provide current in one direction. Conductive wire(s) 145 is wrapped around an upper portion of the chamber. The wires 145 provide current in another direction, which is opposite of the direction of wires 140. The combination of these wires and the rf source provides a high-density plasma discharge.

While the above description is generally described in a variety of specific embodiments, it will be recognized that the invention can be applied in numerous other ways. For example, the improved plasma source design can be combined with the embodiments of the other FIGS. Additionally, the embodiments of the other FIGS. can be combined with one or more of the other embodiments. The various embodiments can be further combined or even separated depending upon the application. Accordingly, the present invention has a much wider range of applicability than the specific embodiments described herein.

### Experiments

To prove the principles and operation of the present invention, experiments were performed. In these experiments, a chamber having a diameter of about thirty inches and a height of about thirty-six inches was used. The chamber was made of stainless steel. Waban Technology, Inc. of Massachusetts (now Silicon Genesis Corporation) provided the chamber. A single inductive flat pancake coil was placed on an upper region of the chamber. The inductive coil was placed on a substantially planar window, which was concentrically aligned overlying a susceptor region of the chamber. The inductive coil was a 10-inch diameter copper coil, which was wrapped about 5 times about a center region. The inner region of the inductive coil was grounded while the outer region of the coil was subjected to rf power of 13.56 MHz. The overall diameter of the inductive coil was about twelve inches. The power supplied to the coil was maintained at about 4-5 kilowatts during operation. The inductive coil was made of a copper material and had cooling fluid running in the coil to prevent the coil from heating up excessively. A silver plate was coupled to the coil to enhance cooling.

Magnetic sources were constructed by way of insulated wires. A plurality of insulated wires were wrapped surrounding the circumference of the chamber. A first group of wires were wrapped in an upper circumference region of the chamber. About 15 to 20 wraps were made using these wires. In a center region of the chamber, which is above the susceptor, a second group of wires were wrapped about the circumference region of the chamber. About 15 to 20 wraps were made using these wires. A power source was applied to each of the groups of wires. A direct current (“D.C.”) power source of about 5 volts and about 40 Amps. was applied to the top group of wires. A D.C. power source of about 5 volts and about 40 Amps. was applied to the bottom group of wires. Details of applying the proper voltage and current are described in more detail below.

A hydrogen gas source was applied to provide hydrogen gas into the chamber. The hydrogen gas source was semiconductor grade (99.9995%) purity hydrogen gas. The gas entered the chamber at a flow rate of 20 sccm, which was at a temperature of room (or ambient) and pressure of a few milli-torr. A mass flow controller was used to selectively introduce the hydrogen gas into the chamber. The mass flow controller was made by a company called MKS. The mass flow controller selectively allowed hydrogen gas to enter into the chamber.

In operation, a work piece such as a blank 8-inch silicon wafer is placed into the chamber. A vacuum pump evacuates the chamber. The vacuum is generally maintained such that the chamber has a pressure of about 0.5 milli-torr or greater during processing. Of course the particular pressure used depends highly upon the application. The vacuum pump can be any suitable unit such as a Turbo Molecular pump made by a company called Varian, but is not limited to such a pump. Hydrogen gas is allowed to enter the chamber. Next, rf power is applied to the ignite the plasma. The rf power is at about 4-5 kW. A glow discharge can be seen through a glass viewing window on the side of the vacuum chamber. The mixture of the hydrogen bearing particles is measured.

A mass spectrometer system was used to measure the relative concentrations of hydrogen bearing particles. In the present example, a mass spectrometer made by a company called Hiden of England was used. Here, a probe was placed into the chamber, as shown. The probe was used at two locations in the chamber to sense the type of hydrogen in the plasma. The probe was inserted into the chamber at a first position, which is against the wall region of the chamber. A measurement was taken at the first position. Next, the probe was moved to a second location in the chamber, as shown. A measurement was taken at the second position. Table 1 lists the mixture of hydrogen bearing particles for two trials. The first trial measures hydrogen for a source where only an rf source is applied. The second trial measures hydrogen for a source that includes the rf source and the magnetic field source.

TABLE 1
List of Concentrations of Hydrogen

| Power Source(s) | Hydrogen (1) | Hydrogen (2) | Hydrogen (3) |
|---|---|---|---|
| Rf source | <1% | 60% | 40% |
| Rf source + field | 99.96% | <1% | <1% |

As seen in Table 1, the concentration of hydrogen bearing particles include hydrogen (1) (e.g., H₁⁺), hydrogen (2) (e.g., H₂⁺ and H₂) and hydrogen (3) (e.g., H₃⁺). By way of inductive coupling from the rf power source, the hydrogen bearing particles include H(1), H(2), and (3). The presence of all three forms of hydrogen is believed to be based upon recombination of certain species of hydrogen at, for example, a wall region. The plasma density using inductive coupling is between about 5×10⁹ and about 5×10¹² ions/cubic centimeter.

The magnetic field is applied to the chamber by way of the D.C. power source(s). The plasma discharge transforms into a state that is dominated by H(1). An inspection of the illumination of the hydrogen discharge through the glass window reveals a higher intensity of light illuminating from the plasma. The illumination is much brighter (i.e., the color turned from blue to magenta) than the plasma discharge made by way of only the rf source. The relative concentrations of hydrogen bearing particles have also changed. Table 1 lists the relative change, where hydrogen (1) is now greater than 99%, hydrogen (2) is less than 0.05%, and hydrogen (3) is less than 0.001%. Accordingly, the plasma discharge becomes substantially hydrogen (1), which we call the “protonic mode” of hydrogen.

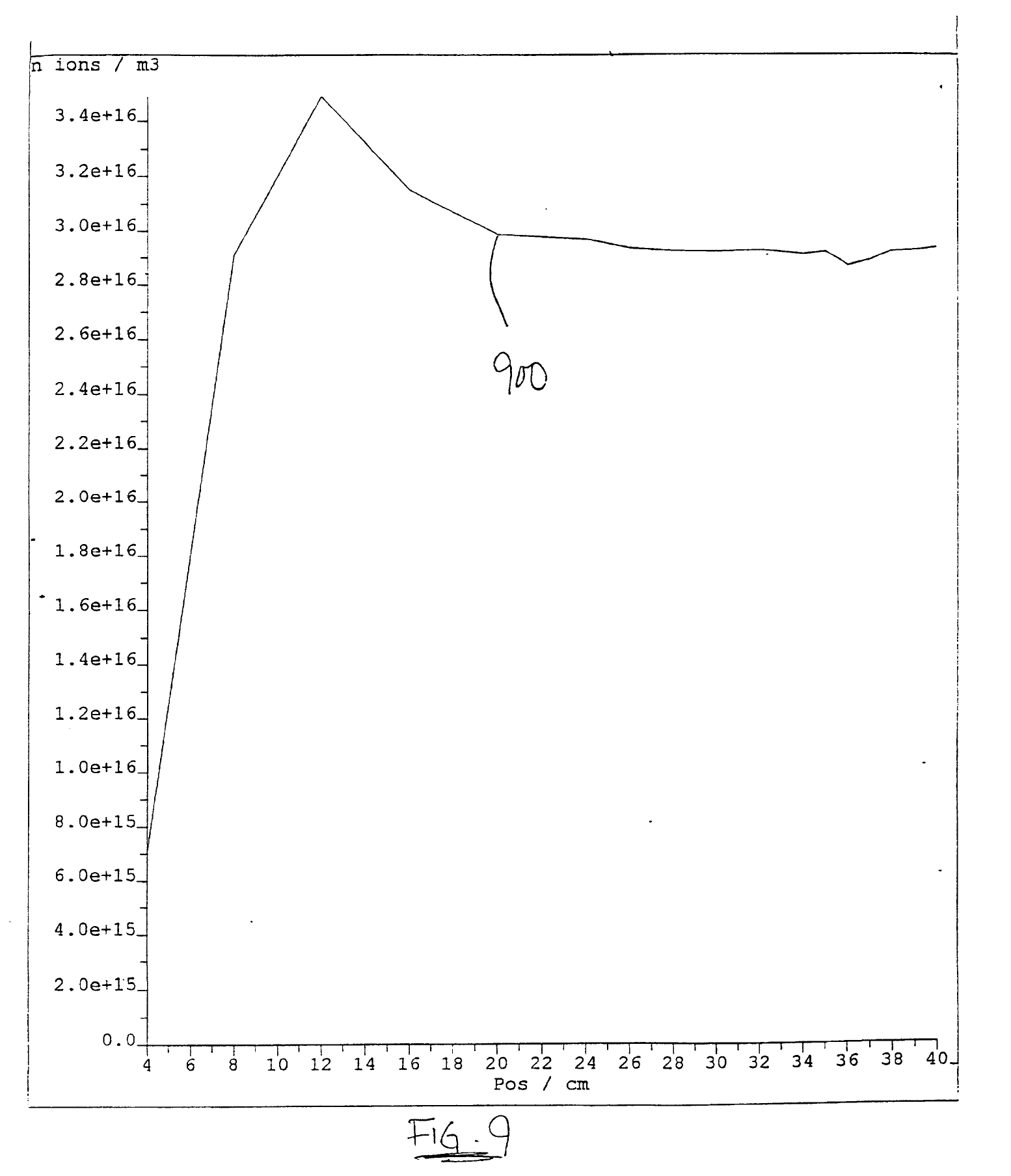

FIG. 8 illustrates a relative measurement of the hydrogen bearing particles. The hydrogen bearing particles include at least H(l), H(2), and H(3). As shown, the left axis illustrates intensity of hydrogen bearing particles in units of counts/second (“SEM”). The lower axis illustrates mass of the hydrogen bearing particles in atomic mass unit (herein “AMU”). The peak near the AMU of value 1 reveals H(1). The smaller peaks near the AMU values of 2 and 3 refer, respectively, to H(2) and H(3). A simple calculation made using the Fig. shows an H(1) concentration relative to H2 and H3 of 99.96% purity, which is believed to be significant. It is believed that present conventional techniques cannot achieve such high purity by way of conventional plasma processing tools and the like.

To implant the hydrogen bearing particles, a voltage bias (i.e., quasi DC pulse) is applied between the plasma and the work piece. The work piece is maintained at a voltage potential of about less than 50 kV. The plasma source has an applied voltage potential of about a few tens of volts. By way of the differential in voltage between the work piece and the plasma discharge, the hydrogen bearing particles are accelerated into the surface of the work piece. The hydrogen bearing particles accelerate through the surface of the work piece and rest at a selected depth underneath the surface of the work piece. It is believed that since the hydrogen bearing particles are substantially a single species, a substantial portion of the plasma implants into the substrate in a similar manner. By way of this manner, a substantially uniform implant is achieved.

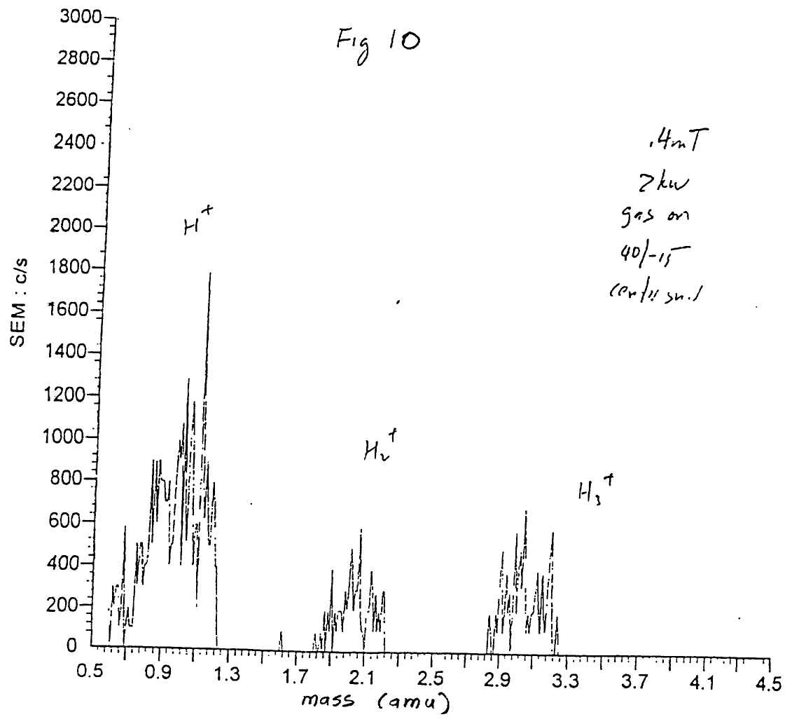

By way of the present plasma source, a high degree of uniformity in the implant is achieved. FIG. 9 is a simplified profile 900 of an implant according to the present experiment. As shown, the particle counts were measured by way of a Langmuir probe. The probe measured a substantial uniform distribution of implanted particles that were measured using the probe. As shown, the concentration centered around 2.9×10¹⁶ ions/m³.

In a specific embodiment, the present invention achieves other ion concentrations, which enhance plasma immersion ion implantation. As merely an example, the hydrogen ion concentration is greater than about 1×10¹⁰ ions/cm³, or greater than about 5×10¹⁰ ions/cm³, or greater than about 5×10¹¹ ions/cm³, or greater than about 1×10¹² ions/cm³. Conventional ICP sources yielded no greater than about 1×10⁹ hydrogen ions/cm³ using similar plasma tools. Accordingly, the present plasma source yields about 100 times or 200 times higher plasma densities than conventional tools.

Although the above has been generally described in terms of a PIII system, the present invention can also be applied to a variety of other plasma systems. For example, the present invention can be applied to a plasma source ion implantation system or plasma etch system. Alternatively, the present invention can be applied to almost any plasma system where ion bombardment of an exposed region of a pedestal occurs. Accordingly, the above description is merely an example and should not limit the scope of the claims herein. One of ordinary skill in the art would recognize other variations, alternatives, and modifications.

### Production of Pure Atomic Hydrogen Ions

The present disclosure teaches the generation of a pure monatomic ion plasma, such as an H₁⁺ plasma that is suitable for plasma immersion ion implantation (PIll). Such a plasma can be used, for example for the SPLIT® (separation by plasma implantation technology) process. SPLIT® is a trademark of Silicon Genesis corporation of Campbell, Calif. This disclosure also teaches the production of essentially a single ionic species plasma from molecular gases for applications in semiconductor manufacturing requiring extreme uniform ionic species spatial and energy profiles.

The production of an atomic hydrogen ion plasma is important for achieving high energy purity plasma ion implant with the deepest implant range. In a normal hydrogen plasma, three ionic species exist H₁⁺, H₂⁺ and H₃⁺. The production of H₂⁺ mainly from electron impact ionization of the H₂ gas according to the reaction

e+H₂→H₂⁺+2e (1)

When the neutral gas pressure is high, H₃⁺ could dominate by a non-resonant ion charge exchange collision according to the reaction:

H₂⁺+H₂→H₃⁺+H (2)

To achieve a pure H₁⁺ plasma, one must maximize the following reactions:

e+H₂→2H+e (3)

e+H→H₁⁺+2e (4)

e+H₂⁺→H₁⁺+H+e (5)

The rate of interaction for a given atomic process such as electron impact ionization, dissociation and charge exchange can be described by a rate coefficient <σv> where σ_{I} us the cross-section averaged over the velocity v relative to stationary target particles. The particles are assumed to have a Maxwellian velocity distribution. The dominant processes are electron impact ionizations, such as those described by equations (1) and (4) and electron impact dissociations, such as those described by equations (3) and (5). The charge exchange rate, as described by equation (2) can be significantly reduced by operating below 0.5 mTorr of hydrogen neutral pressure.

The rate coefficients for equations (3) through (5) have the following value for a sufficiently high electron temperature Tₑ of order 20 eV.

There are two paths to produce H₁⁺ ions. Equations (1) and (5) and (4) or via equations (3) and (4). These types of dissociation ionization events have various threshold energies. For a threshold energy of E₀, the fraction f(E>E₀) of electrons in a Maxwellian distribution of electron temperature Tₑ, that have an energy greater than E₀ is given by the equation:

$$f ( E > {E}_{0} ) = \frac{2}{\sqrt{π}} {\int }_{{E}_{0} / {T}_{e} }^{∞} \sqrt{{E}_{0} / {T}_{e}} exp ( - {E}_{0} / {T}_{e} ) ⅆ ( {E}_{0} / {T}_{e} )$$

Where the Tₑ is measured in eV. For a threshold energy of 16 eV, the usable electron fraction in Tₑ=4 eV compared with Tₑ=8 eV is roughly 1:5. A high electron temperature plasma is the key to maximizing reactions (1), (3), (4) and (5). However, the heating of the electron temperature in the main Maxwellian distribution function may not be enough for the dissociative ionization of H₁⁺ production from the H₂ molecules. The dissociative ionization cross-section typically has a maximum value at an electron energy of about 100 eV. The use of helicon wave and/or electron cyclotron wave heating of electrons at 100 eV by matching of phase velocity the wave becomes important. The present PIII reactor design takes advantage of the increase in H₂ ionization and dissociation by a combination of efficient energy coupling into both the bulk (Maxwellian) electrons and the high energy, e.g. 100 eV, electrons. This also points the way towards producing atomic or molecular species of ions for a given plasma. For example, in oxygen PIII or SPIMOX, atomic oxygen ions (O⁺) are the desirable species over molecular oxygen ions (O₂⁺) because of the implant depth.

The maximum dissociative ionization cross-section in oxygen typically occurs at an electron energy of about 150 eV, i.e., about 50 eV more than for hydrogen. A similar process of tuning the rf wave phase velocity to maximize electron concentration in an oxygen plasma could produce O⁺ ion dominated PIII for SPIMOX.

<σv>₁, <σv>₂ produces H₂⁺ and H₃⁺, respectively

<σv>₃˜1×10⁻⁸ cm⁻³/sec

<σv>₄˜1.3×10⁻⁸ cm⁻³/sec

<σv>₅˜1.3×10⁻⁷ cm⁻³/sec

The rate coefficients for dissociation of H₂ into H and H₂⁺ and H, plus the ionization of H are the rate coefficients that maximize the H₁⁺ density in the plasma.

The loss of H₁⁺ and H through recombination at the wall can be minimized by a cusped, magnetic field configuration such as that shown in FIG. 2. Specifically magnetic field B has point cusps 217, 219 at top and bottom ends and a ring cusp 218 in the between point cusps 217, 219. In addition rows of permanent magnets located on the wall of the chamber proximate the location of ring cusp 218 may be used to produce multiple cusps to reduce electron loss through ring cusp 218. In such a magnetic cusp configuration, the plasma reaches the chamber wall through point cusps 217, 219 and ring cusp 218. In one embodiment, plasma is injected from the top point cusp 217 while the wafer holder 82 blocks the lower point cusp 217. Electrons leave ring cusp 218 but can be reflected by two mechanisms. First, electrons travelling towards a stronger magnetic field region are subject to magnetic mirroring. Secondly, electrons have a higher thermal velocity than ions and, consequently, leave the plasma faster than the ions thereby setting up a net negative space charge. The space charge establishes an ambipolar potential that further reduces electron loss to the ring cusp. Thus, the cusped magnetic field configuration maximizes electron confinement.

Electron confinement is very important to the production of H₁⁺ ions. The collisional mean free path for the type of reactions listed in equations (1), (3), (4) and (5) is given by:

λ₅=v_{H2+}/nₑ<σv>₅ (6)

where λ₅ is the mean free path for electron impact dissociation described by equation (5) and v_{H2+} is the velocity of the H₂⁺ ions and nₑ is the electron density. In general, better electron confinement tends to maximize the production rate of H₁⁺ ions according to:

$$\frac{ⅆ {n}_{{H}_{1}^{+}}}{ⅆ t} = ( {n}_{{H}_{2}^{+}} ) ( {n}_{e} ) < σ v {>}_{5} \qquad ( 7 )$$

where n_{H1+}, the density of H₁⁺ ions produced from equation (5) is maximized by having a high reaction rate in equations (1), (3), (4) and (5) due to the increase in electron confinement. Notice that the production of H₃⁺ ions depends on charge exchange of H₂⁺ ions off H₂ molecules. If H₂⁺ ions and H₂ molecules are breaking off into H₁⁺ ions and H atoms before a charge exchange event can occur, the production of H₁⁺ ions will dominate. H₁+ions can recombine with electrons at the wall. Our magnetic confinement effectively reduces the available wall area to less than the ring cusp region, which further promotes H₁⁺ ion concentration.

### Plasma Heating by Helicon Waves

One of the mechanisms by which electrons in a plasma can be heated by rf energy is through helicon waves. The difference between an inductively coupled plasma (ICP) and a helicon is that the rf energy absorption in an ICP takes place primarily near the antenna, while in a helicon type source absorption can take place relatively far away from the antenna. Electrons trapped in the waves can be accelerated up to the phase velocity while remaining in synchronism with the wave. This phenomena is referred to as Landau damping. After losing a large fraction of its energy in an ionizing or dissociative collision, the energetic electron (often called a primary electron) can be re-accelerated before it is lost to the wall. Proper magnetic confinement, as with a cusp field, allows efficient use of the electrons in the plasma, thereby significantly increasing the ionization efficiency of the rf energy.

At low magnetic field values, the helicon wave becomes a helicon-electron cyclotron resonant (ECR) mode having two modes with different dispersion relations. One mode is a whistler wave with a dispersion relation given by:

$$\frac{{c}^{2} {k}^{2}}{{ω}^{2}} = 1 - \frac{{ω}_{p}^{2}}{ω ( ω - {ω}_{C} cos θ )} \qquad ( 8 )$$

where ω is the wave frequency in rad/sec, k is the wave number, ωₚ is the electron plasma frequency and ω_{c} is the cyclotron frequency of the electrons.

The other mode is an electron cyclotron wave, also known as a Trivelpiece-Gould mode in finite geometry situations such as the inside of a PIII reactor with conducting boundary conditions. The dispersion relation for the Trivelpiece-Gould mode is given by:

$${β}^{2} = {k}^{2} {\frac{{ω}_{c}^{2}}{{ω}^{2}} [ 1 + \frac{{ω}_{c}^{2}}{{ω}_{p}^{2}} ]}^{- 1} \qquad ( 9 )$$

In solving equation 9 with conducting boundary conditions and including the finite mass of the electron at low magnetic field, there exists a threshold magnetic field below which, the helicon cannot exist.

Chen and Decker have observed an ion density peak in a helicon discharge at low magnetic fields. At low magnetic fields, the Trivelpiece-Gould mode dominates the electron heating and deposits its wave energy near the edge region. At low gas pressures, e.g. less than about 1 mTorr, the energy absorption by electrons is in the form of collisionless Landau damping instead of collisional damping. As such, the energetic electron production is from the resonant electrons having velocities near the wave phase velocity.

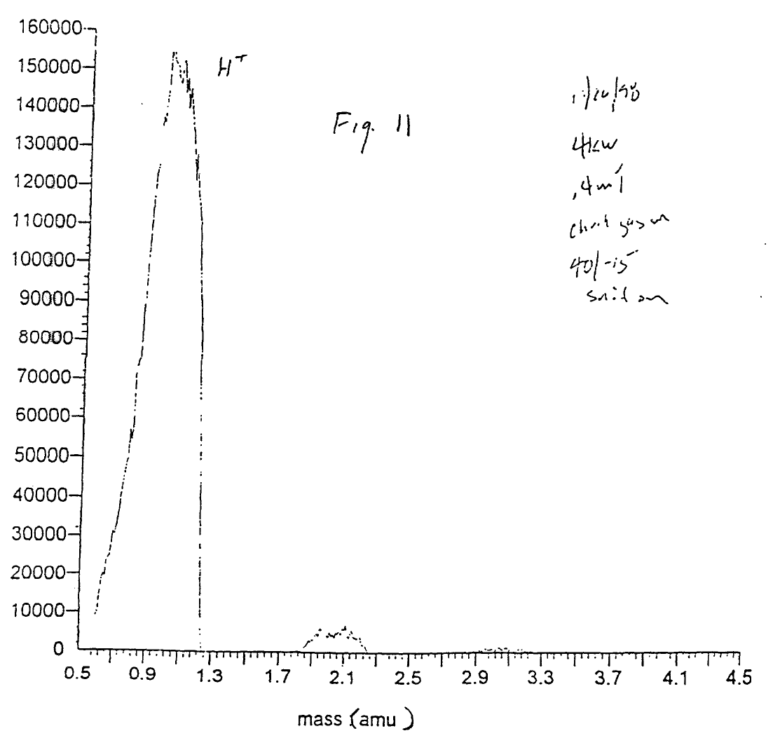

FIGS. 10, and 11 show ion mass spectrometer data at the center of the plasma for different applied powers of 2 kW and 4 kW respectively. As shown in FIGS. 10 and 11, the higher applied rf power increases the H₁⁺/H₂⁺ ratio from about 3:1 at 2 kW to almost 30:1 at 4 kW. Furthermore, it is found experimentally that the center of the plasma has a lower H₁⁺/H₂⁺ ratio compared to the edge of the plasma. This experimental evidence is consistent with the conjecture that the Trivelpiece-Gould mode plays a significant role in electron heating in pure H₁⁺ plasma conditions. The present rf coil and magnetic field configuration compensate for the H₁⁺ species uniformity across the plasma, or across the surface of the target, by maximizing the rf field in the center region of the chamber.

A magnetic cusp field configuration provides several additional advantages such as enhanced plasma stability and confinement time for the electrons. The magnetic cusp field also tends to redirect the trajectories of secondary electrons emitted during high voltage implantation which helps minimize damage sensitive chamber components such as dielectric windows 26 shown in FIG. 1.

Other techniques can be used to achieve pure H₁⁺ PIII. For example, a magnetic field can be added to increase the efficiency of the ICP antenna by cyclotron resonant waves. A diverging magnetic field could be used to fan-out the high-density plasma for plasma uniformity enhancement. It is also possible to use a high electron temperature and/or the energetic electron “tail” of the electron energy distribution to maximize H₁⁺ ion density relative to H₂⁺. A low neutral pressure helps minimize the production of H₃⁺ ions. High H₁⁺ ion density (10¹¹ to 10¹² cm⁻³) can reduce the sheath thickness during implantation to minimize collisions of H₁⁺ ions traversing the sheath for implant energy purity.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A plasma immersion ion implantation (PIII) system, said system comprising:
a chamber;
a susceptor disposed within an interior region in said chamber, said susceptor being adapted to secure a work piece thereon;
an rf source disposed overlying said susceptor in said chamber, said rf source providing an inductive discharge to form a plasma from a gas within said chamber;
a first electro-magnetic source disposed surrounding said susceptor in said chamber, said first magnetic source providing focused magnetic field lines toward said susceptor; and
a second-electro magnetic source disposed surrounding said susceptor in said chamber, said second magnetic source providing focussed magnetic field lines toward said susceptor.

2. The system of claim 1 wherein said rf source is a single coil disposed overlying an upper surface of said chamber.

3. The system of claim 1 wherein said rf source comprises a plurality of coils, each of said coils being disposed overlying an upper surface of said chamber.

4. The system of claim 2 further comprising a tuning circuit coupled to said rf source.

5. The system of claim 1 wherein said plasma comprises a first cusp region toward said rf plasma source and a second cusp near a chamber side.

6. The system of claim 1 wherein said plasma comprises a first cusp region toward said susceptor and a second cusp near a chamber side.

7. The system of claim 1 wherein said first electro-magnetic source and said second electro-magnetic source prevent a substantial portion of said plasma from occupying a region directly adjacent to a wall of said chamber.

8. The system of claim 1 wherein said first electro-magnetic source is coupled to a direct current power supply.

9. The system of claim 1 wherein said second electro-magnetic source is coupled to a direct current power supply.

10. The system of claim 1 wherein said first electro-magnetic source is coupled to a direct current power supply, said direct current power supply providing current that flows in a first direction.

11. The system of claim 10 wherein said second electro-magnetic source is coupled to a direct current power supply, said direct current power supply providing current that flows in a second direction, said second direction being opposite of said first direction.

12. The system of claim 1 further comprising a source of hydrogen gas, said source being coupled to said chamber.

13. The system of claim 1 wherein said plasma is a hydrogen bearing plasma.

14. The system of claim 1 wherein said plasma is substantially a hydrogen bearing plasma of H₁⁺ particles.

15. The system of claim 1 further comprising a power source coupled between said susceptor and said plasma.

16. The system of claim 15 wherein said power source capable of accelerating particles from said plasma into and through a surface of said work piece to a selected depth underlying said surface of said work piece.

17. The system of claim 1 wherein said chamber is a vacuum chamber that is maintained at a pressure of about 0.1 millitorr to about 1.0 milltorr.

18. A plasma immersion ion implantation (PIII) source, said source comprising:
a vacuum chamber;
a susceptor disposed within an interior region in said chamber, said susceptor being adapted to secure a work piece thereon;
an rf source disposed overlying said susceptor in said chamber, said rf source providing an inductive discharge to form a plasma from a gas within said chamber; and
a first electro-magnetic source disposed surrounding an upper portion of said chamber, said first magnetic source providing a first cusp region of said plasma toward said rf source.

19. The source of claim 18 further comprising a second electro-magnetic source disposed surrounding a lower portion of said chamber, said second electro-magnetic source providing a second cusp region of said plasma toward said susceptor.

20. The source of claim 18 wherein said first electro-magnetic source is coupled to a direct current power source.

21. The source of claim 18 wherein said rf source is a single coil disposed overlying an upper surface of said chamber.

22. The source of claim 21 wherein said coil is configured to maximize an rf power delivered to a center of a plasma within said chamber.

23. The source of claim 21, wherein said rf source, said first magnetic source and said second magnetic source are configured to couple helicon waves to a plasma within said chamber.

24. A method for producing a substantially pure monatomic ion species in a plasma in a chamber for plasma immersion ion implantation (PIII), the method comprising:
providing an inductive discharge to form a plasma from a gas within said chamber;
providing a first set of focused magnetic field lines within the chamber that form a first cusp proximate a first end of the chamber; and
providing a second set of focused magnetic field lines within the chamber that form a second cusp proximate a second end of the chamber, wherein the first and second sets of magnetic field lines interact to form a third cusp intermediate the first and second cusps.

25. The method of claim 24 wherein further comprising:
coupling rf energy to the gas within the chamber.

26. The method of claim 25 wherein the rf energy excites a helicon electron cyclotron resonance mode of the plasma.

27. The method of claim 26 wherein the rf energy excites a Trivelpiece-Gould mode of the plasma.

28. The method of claim 24 wherein the plasma is used for a plasma ion implantation process.

29. The method of claim 24 wherein the plasma is used for a separation by plasma implantation technology process.

30. The method of claim 24 wherein the plasma is substantially a monatomic hydrogen ion plasma.
